(19) United States
(12) Patent Application Publication
(10) Pub. No.: US 2026/0235946 A1
(43) Pub. Date: Aug. 13, 2026

(54) SUB-RESOLUTION ASSIST FEATURE GENERATING METHOD, AND MASK MANUFACTURING METHOD INCLUDING THE GENERATING METHOD

(71) Applicant: Samsung Electronics Co., Ltd., Suwon-si (KR)

(72) Inventors: Wooyong Cho, Suwon-si (KR); Bayram Yenikaya, San Jose, CA (US); Joobyoung Kim, San Jose, CA (US); Useong Kim, Suwon-si (KR); Kyungwook Nam, Suwon-si (KR); Heejun Lee, Suwon-si (KR)

(21) Appl. No.: 19/048,318

(22) Filed: Feb. 7, 2025

(51) Int. Cl. G03F 1/72; G06T 7/00; G06T 7/11; G06T 11/20

(52) U.S. Cl. CPC G03F 1/72; G06T 7/0004; G06T 7/11; G06T 11/26; G06T 2207/20021; G06T 2207/30148; G06T 2210/56

(57) ABSTRACT

A sub-resolution assist feature generating method includes performing inverse lithography technology (ILT) on a first main feature to generating an ILT image, generating a first point cloud map including a plurality of points for the first main feature, symmetrizing the first point cloud map based on the ILT image, serializing the symmetrized first point cloud map, extracting a seed for generating a sub-resolution assist feature (SRAF), based on the serialized first point cloud map, and generating the SRAF based on the seed.

### BACKGROUND

The inventive concept relates to a method of manufacturing a mask, and more particularly, to a mask manufacturing method including a sub-resolution assist feature (SRAF) generating method.

In a semiconductor process, a photolithography process using a mask may be performed to form a pattern on a semiconductor substrate, such as a wafer. A mask, simply put, is a pattern transfer material in which an opaque material pattern shape is formed on a transparent base material. To briefly describe a mask manufacturing process, first, a required circuit is designed, a layout for the circuit is designed, and then mask design data obtained through optical proximity correction (OPC) is transferred as mask tape-out (MTO) design data. Thereafter, mask data preparation (MDP) is performed based on the MTO design data, and a front end-of-line (FEOL) process, such as an exposure process, and a back end-of-line (BEOL) process, such as a defect inspection, may be performed to manufacture a mask.

### SUMMARY

The inventive concept provides a sub-resolution assist feature (SRAF) generating method with increased consistency and a mask manufacturing method including the SRAF generating method.

The problems to be solved by the inventive concept are not limited to the problems mentioned above, and other problems may be clearly understood by those skilled in the art from the description below.

According to an aspect of the present disclosure, a sub-resolution assist feature generating method includes performing inverse lithography technology (ILT) on a first main feature to generating an ILT image, generating a first point cloud map including a plurality of points for the first main feature, symmetrizing the first point cloud map based on the ILT image, serializing the symmetrized first point cloud map, extracting a seed for generating a sub-resolution assist feature (SRAF), based on the serialized first point cloud map, and generating the SRAF based on the seed.

According to an aspect of the present disclosure, a sub-resolution assist feature generating method includes segmenting a full shot layout into a plurality of patches, performing inverse lithography technology (ILT) on a main feature of at least one of the plurality of patches to generate an ILT image, generating a point cloud map including a plurality of points for the main feature, symmetrizing the point cloud map based on the ILT image, serializing the symmetrized point cloud map, extracting a seed for generating a sub-resolution assist feature (SRAF) based on the serialized point cloud map, and generating the SRAF based on the seed.

According to an aspect of the present disclosure, a mask manufacturing method includes performing inverse lithography technology (ILT) on a main feature to generate an ILT image, generating a point cloud map including a plurality of points for the main feature, symmetrizing the point cloud map based on the ILT image, serializing the symmetrized point cloud map, extracting a seed for generating a sub-resolution assist feature (SRAF) based on the serialized point cloud map, generating the SRAF based on the seed, performing mask rule check (MRC) on the SRAF, determining whether there is a defect on the SRAF in the performing of the MRC, transferring a layout image including the main feature and the SRAF as mask tape-out (MTO) design data when there is no defect, preparing mask data based on the MTO design data, and exposing a mask substrate based on the mask data.

### BRIEF DESCRIPTION OF THE DRAWINGS

Embodiments will be more clearly understood from the following detailed description taken in conjunction with the accompanying drawings in which:

FIG. 1 is a flowchart illustrating a method of generating a sub-resolution assist feature (SRAF), according to an embodiment;

FIG. 2 is a diagram illustrating a portion of a layout of a full shot design including a plurality of patches according to an embodiment;

FIG. 3 is an enlarged diagram of a first patch of FIG. 2;

FIG. 4 is a diagram illustrating a method of finding a unique shape segment, according to an embodiment;

FIG. 5 is a diagram illustrating a method of finding a unique shape point, according to an embodiment;

FIG. 6 is a flowchart illustrating a method of generating a point cloud map, according to an embodiment;

FIGS. 7 to 10 are drawings illustrating generating a point cloud map according to an embodiment;

FIG. 11 is a diagram illustrating a point cloud map according to an embodiment;

FIG. 12 is a diagram illustrating a combination of point cloud maps of a plurality of main features;

FIG. 13 is a flowchart illustrating a process of symmetrizing a point cloud map, according to an embodiment;

FIG. 14 is a drawing illustrating the arrangement of unique shape points of a main feature according to an embodiment;

FIG. 15 is a diagram illustrating relative coordinates of all points of a point cloud map using each unique shape point of a main feature as a reference point according to an embodiment;

FIG. 16 is a diagram illustrating loading an inverse lithography technology (ILT) image onto a point cloud map according to an embodiment;

FIG. 17 is a diagram illustrating an ILT image corresponding to region A of FIG. 16;

FIG. 18 is a diagram illustrating a point cloud map and an ILT image corresponding to region A of FIG. 16;

FIG. 19 is a diagram illustrating values inside points of a point cloud map corresponding to region A of FIG. 16;

FIG. 20 is a diagram illustrating a continuous point cloud map according to an embodiment;

FIG. 21 is a diagram illustrating a position of a seed extracted from a point cloud map including two main features;

FIG. 22 is a diagram illustrating an SRAF generated based on a seed of FIG. 21; and

FIG. 23 is a flowchart illustrating a mask manufacturing method according to an embodiment.

### DETAILED DESCRIPTION OF THE EMBODIMENTS

Hereinafter, embodiments are described in detail with reference to the attached drawings. The same reference numerals are used for identical components in the drawing, and redundant descriptions thereof are omitted. In the drawings below, the thickness and size of each layer are exaggerated for convenience and clarity of description, and thus may differ somewhat from the actual shape and proportion.

Here, terms indicating spatial positions, such as “bottom,” “below,” “lower,” “upper,” and the like, are used only for the purpose of describing the relative positional relationship between elements or features depicted in the drawings, are for ease of understanding only, and do not limit the inventive concept in any sense. Terms referring to relative positions in space are intended to encompass variations in the orientation of semiconductor devices other than those disclosed in the drawings. That is, semiconductor devices may be oriented in various directions during use (or during manufacture), and even in such cases, terms for positions used in this specification are readily understood by those skilled in the art.

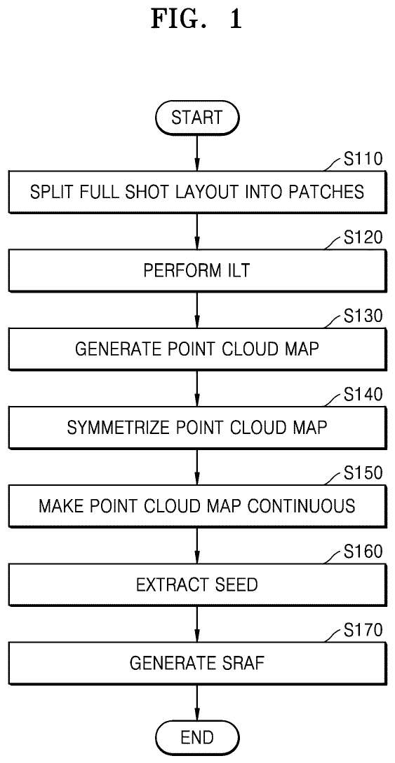

FIG. 1 is a flowchart illustrating a method of generating a sub-resolution assist feature (SRAF), according to an embodiment.

Referring to FIG. 1, a full shot layout may be segmented into a plurality of patches including one or more main features (S110). The main feature may correspond to a target pattern to be formed on a substrate, such as a wafer. Such a target pattern may be formed by transferring a pattern on a mask onto the substrate through an exposure process. Accordingly, first, a layout for a pattern on a mask corresponding to a target pattern, i.e., a mask layout, may be designed. Due to the nature of the exposure process, the shape of the target pattern may be different from the shape of the pattern on the mask. The pattern on the mask is reduced and projected and transferred onto the substrate, and thus the pattern on the mask may have a larger size than the target pattern. The main feature may represent the critical components of a semiconductor device. The main feature may be defined in the original design files such as GDSII and OASIS format.

As patterns become finer, the optical proximity effect (OPE) caused by the influence of neighboring patterns may occur during the exposure process, and to overcome the OPE, optical proximity correction (OPC) may be performed to suppress the occurrence of OPE by correcting the mask layout. OPC is broadly divided into two types: rule-based OPC and simulation-based or model-based OPC. Model-based OPC may be advantageous in terms of time and cost because model-based OPC uses only the measurement results of representative patterns without having to measure all of the large number of test patterns. OPC may include not only variations of the mask layout but also methods of adding sub-lithographic features, called serifs, on the corners of the pattern in a broad sense or methods of adding SRAFs, such as scattering bars. Accordingly, the method of generating a curve SRAF of the present embodiment may be included in OPC. In an embodiment, the curve SRAF may refer to generating assist features or regions along a curve derived from a point cloud map. The generating of the curve SRAF may include defining a continuous curve (or spline) based on the map, and then identifying seed points or features for enhancement. The SRAF is an auxiliary pattern introduced to solve the problem of deviation due to OPC caused by different diffraction patterns in each region due to optical characteristics when patterns are formed in high-density and low-density regions within a chip. This SRAF is not a pattern actually formed on a wafer.

Inverse lithography technology (ILT) is one of the most important technologies for curvilinear masks and is one of OPCs. General OPCs work by finely chopping the edges of a pattern and moving them up, down, left, and right or by inserting quadrangular auxiliary features based on rules to correct distortion caused by diffraction. Meanwhile, calculating the image transferred from a photomask to a wafer surface may be obtained by mathematically expressing an optical system. This is called a forward function, and ILT is technology for finding an inverse function of the forward function.

The OPC process may be briefly described as follows: First, basic data for OPC is prepared. Next, an OPC model including an optical OPC model and an OPC model for photoresist PR is generated. Thereafter, OPC-ed layout images or data are acquired through a simulation process using the OPC model. Mask rule check (MRC) is performed on the OPC-ed layout images. The MRC may refer to a check for limitations on a width or spacing within which the pattern has to be maintained when manufacturing a mask. For example, when manufacturing a mask, there may be a mask process limitation, that is, a limitation that the width of a pattern cannot be made smaller than a set minimum width or the spacing between patterns cannot be made smaller than a set minimum spacing. Therefore, performing or verifying MRC may refer to a process of checking whether the limitations are observed for the mask layout. By performing MRC, the final OPC-ed layout image may be obtained. The final OPC-ed layout images may then be transferred to a mask manufacturing team, as mask tape-out (MTO) design data for subsequent mask manufacturing.

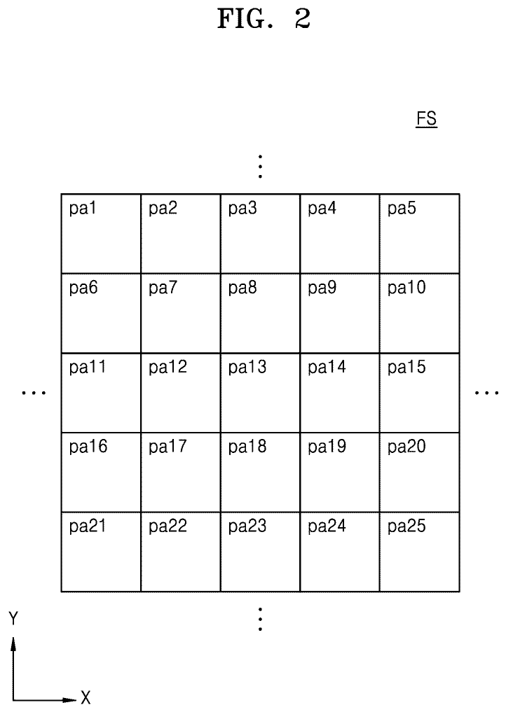

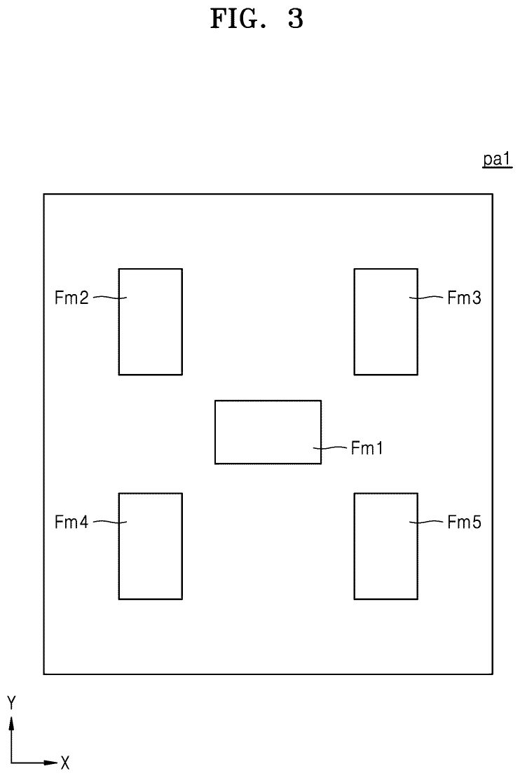

A patch may include one or more main features. The entire region occupied by a plurality of target patterns to be formed on a substrate, such as a wafer, may be segmented into one or more patches. In an implementation, patches may be segmented so that the amount of OPC calculations may be reduced. The operation (S110) of segmenting the full shot (FS in FIG. 2) layout into a plurality of patches including one or more main features is described with reference to FIGS. 2 and 3 together.

FIG. 2 is a diagram illustrating a portion of a layout of a full shot design including a plurality of patches according to an embodiment, and FIG. 3 is an enlarged diagram of a first patch of FIG. 2.

Referring to FIGS. 2 and 3, the full shot FS may be the entire region of a lithography mask that may be transferred to a wafer (or photoresist formed on a wafer) in a single exposure. Lithography is technology of transferring a pattern of a pre-prepared mask onto a wafer through an exposure and development process. In an embodiment, the pattern formed on a lithography mask has a larger size than an actual pattern to be implemented, and thus, the pattern may be scaled down and transferred onto the wafer. Because the patterns implemented on actual wafers are very fine, a pattern larger than the actual pattern may be formed on a lithography mask, thereby improving the precision of pattern formation.

The full shot FS may have a length of, for example, about 26 mm horizontally and about 33 mm vertically. The design layout on the full shot FS may include two-dimensional patterns. For convenience of description, the orthogonal directions of the design layout are defined as a first horizontal direction (an X-direction) and a second horizontal direction (a Y-direction). Patches pa1 to pa25 have a length of about 1 mm in both the horizontal and vertical directions, and millions of patches pa1 to pa25 may be arranged in one full shot FS. The patches pa1 to pa25 may be arranged to form a matrix in the first horizontal direction (the X-direction) and the second horizontal direction (the Y-direction). The edges of each of the patches may be substantially parallel to any one of the first horizontal direction (the X-direction) and the second horizontal direction (the Y-direction).

Each of the plurality of patches pa1 to pa25 may include one or more main features. In FIG. 3, first to fifth main features Fm1, Fm2, Fm3, Fm4, and Fm5 are illustrated as being arranged in the first patch pa1, but the inventive concept is not limited thereto. For example, each patch may include four or less main features or six or more main features.

To minimize computation, a full shot FS layout may be segmented into a plurality of patches so that the number of same type of patches is maximized. The same type of patches may be patches having the same shape of the main features and/or the same arrangement of the main features within the patches. That is, the full shot FS layout may be segmented into a plurality of patches so that different types of patches are minimized.

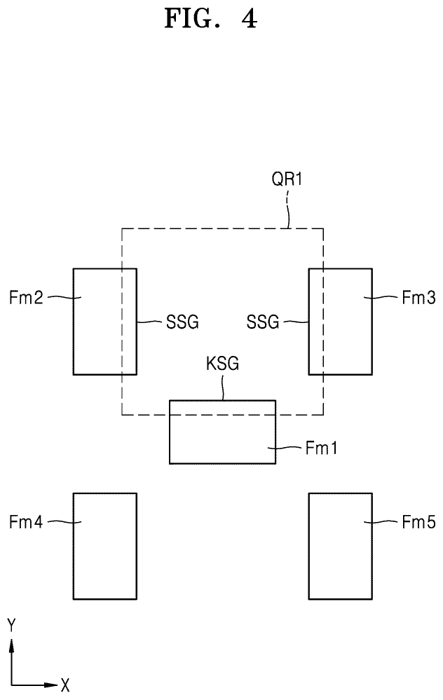

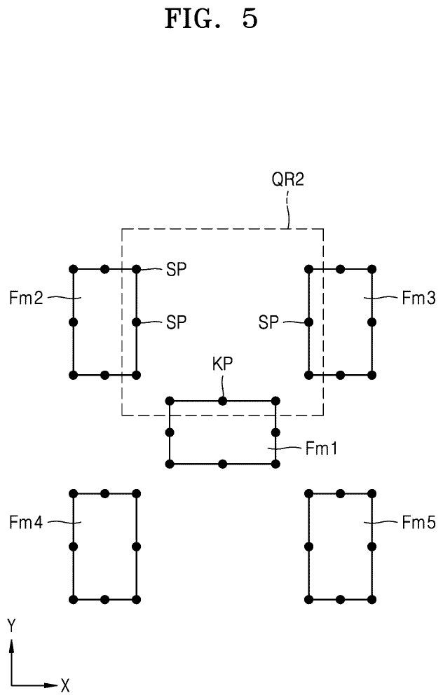

Referring to FIG. 1, after the full shot FS is segmented into the plurality of patches (S110), ILT may be performed (S120). ILT may be performed on every unique shape point and/or every unique shape segment. ILT is performed, and an ILT image may be generated. A method of finding a unique shape segment and a unique shape point of the main feature are described with reference to FIGS. 4 and 5 together.

FIG. 4 is a diagram illustrating a method of finding a unique shape segment, according to an embodiment, and FIG. 5 is a diagram illustrating a method of finding a unique shape point, according to an embodiment.

Referring to FIG. 4, in order to find a unique shape segment, each main feature may be segmented into a plurality of segments. Thereafter, a hash value may be generated for each of the segments.

First, a hash value of a key segment KSG among the segments may be calculated. The key segment KSG may be one of the segments of a main feature Fm. For example, a first query region QR1 may be generated based on the key segment KSG. The first query region QR1 may be a peripheral region that optically affects the key segment KSG. The first query region QR1 may include the key segment KSG and a surrounding segment SSG. Within the first query region QR1, all segments, excluding the key segment KSG, may be surrounding segments SSG.

A hash value may be calculated based on the key segment KSG and the surrounding segment SSG within the first query region QR1. In an embodiment, the hash value may be calculated based on the length of a key segment KSG, the length of the surrounding segment SSG, and/or the distance between the key segment KSG and the surrounding segment SSG. That is, the hash value may be calculated based on the characteristics of the key segment KSG itself and surrounding conditions.

Referring to FIG. 5, in order to find a unique shape point, each main feature may be segmented into a plurality of points. Thereafter, a hash value may be generated for each of the points.

First, hash values of the points may be calculated. For example, a second query region QR2 may be generated based on a key point KP. The key point KP may be one of the points of the main feature Fm. The second query region QR2 may be a surrounding region that optically affects the key point KP. The second query region QR2 may include a key point KP and a surrounding point SP. Within the second query region QR2, all points, excluding the key point KP, may be a surrounding point SP.

A hash value may be calculated based on the key point KP and surrounding point SP within the second query region QR2. In an embodiment, a hash value may be calculated based on an array of the key point KP and the surrounding point SP. In an embodiment, a hash value may be calculated based on the distance between the key point KP and the surrounding point SP. That is, a hash value may be calculated based on the characteristics of the key point KP itself and the surrounding conditions.

Here, the hash value refers to an output value of a hash function. The hash function may convert the features of a segment (or point) into a unique value. That is, segments (or points) with the same hash value may be segments (or points) with the same geometric features. For every segment (or point), a hash value may be output, and segments (or points) with different hash values (i.e., with different geometrical features) may be selected as unique shape segments (or unique shape points). The unique shape segments may be referred to as segments of interest, and the unique shape points may be referred to as points of interest.

Referring to FIG. 1, after the ILT is performed (S120), a point cloud map PCM for the main feature may be generated (S130). The point cloud map PCM may be a set of data points for a space.

The point cloud map PCM may include a plurality of points PT. In an embodiment, the point cloud map PCM may have an elliptical shape. In another embodiment, the point cloud map PCM may have a rectangular shape. However, the shape of the point cloud map PCM is not limited thereto, and the point cloud map PCM may have other shapes. In an embodiment, the shape of the point cloud map PCM may be selected based on the shape of the SRAF.

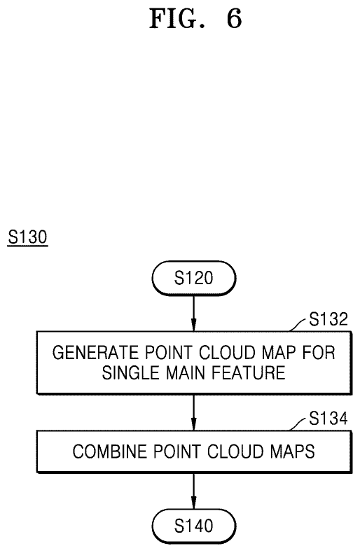

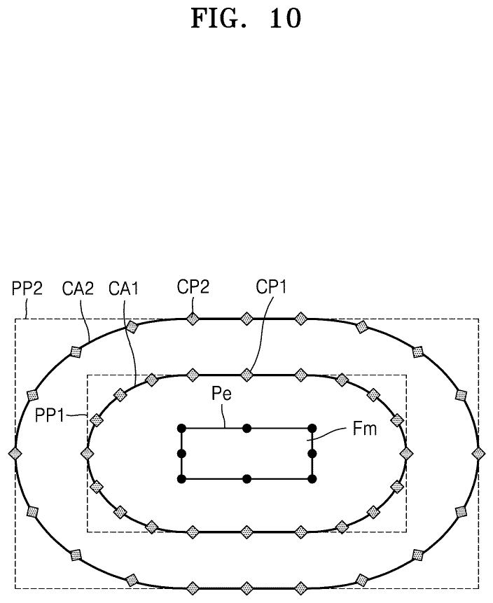

A method of generating a point cloud map PCM is described with reference to FIGS. 6 to 12.

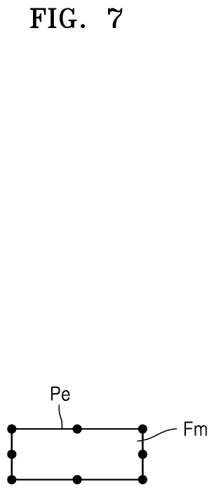

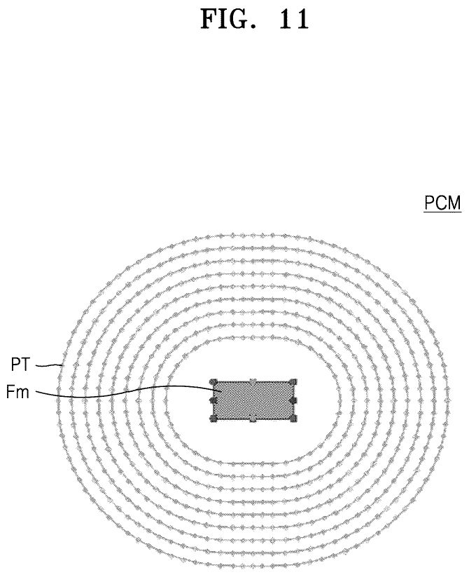

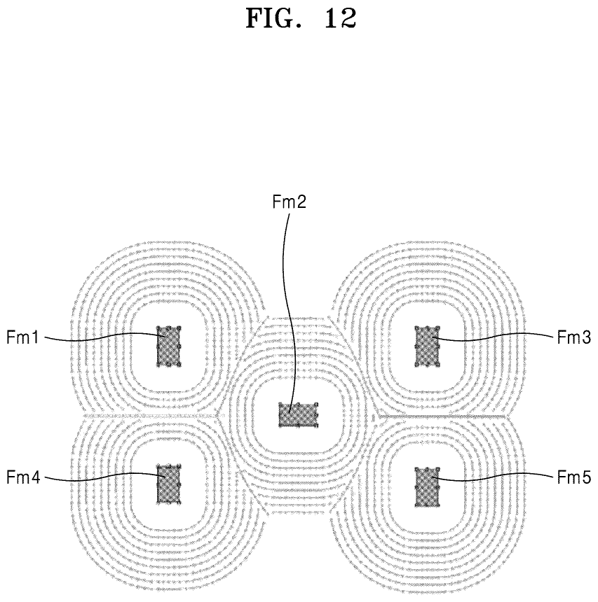

FIG. 6 is a flowchart illustrating a method of generating a point cloud map, according to an embodiment, and FIGS. 7 to 10 are diagrams illustrating generating a point cloud map according to an embodiment. FIG. 11 is a diagram illustrating a point cloud map according to an embodiment. FIG. 12 is a diagram illustrating a combination of point cloud maps of a plurality of main features.

Referring to FIGS. 6 to 12, the operation (S130) of generating a point cloud map PCM for a plurality of main features Fm may include an operation (S132) of forming a point cloud map PCM for each single main feature Fm and an operation (S134) of combining the point cloud maps PCM for each main feature Fm.

In an embodiment, a point cloud map PCM may be generated based on the main features Fm. In an embodiment, a point cloud map PCM may be generated in a rule-based manner. For example, a point cloud map PCM may be generated by adjusting the distance to the main feature Fm, based on rules. For example, a point cloud map PCM may be generated based on a distance from a pre-selected main feature Fm and a distance between points PT of a pre-selected point cloud map PCM.

In an embodiment, a point cloud map PCM may be formed outside the main feature Fm. For example, a space defined by the point cloud map PCM may be larger than a space defined by the main features Fm.

First, to generate a point cloud map PCM for a single main feature Fm, the main feature Fm may be subdivided into a plurality of segmentation edges Pe. The rules for subdividing the edges of a main feature Fm into the segmentation edges Pe may be defined variously. For example, in FIG. 7, the edge of the main feature Fm may be segmented at a preset interval to generate the segmentation edges Pe. The black dots may correspond to subdivision points for edge segmentation.

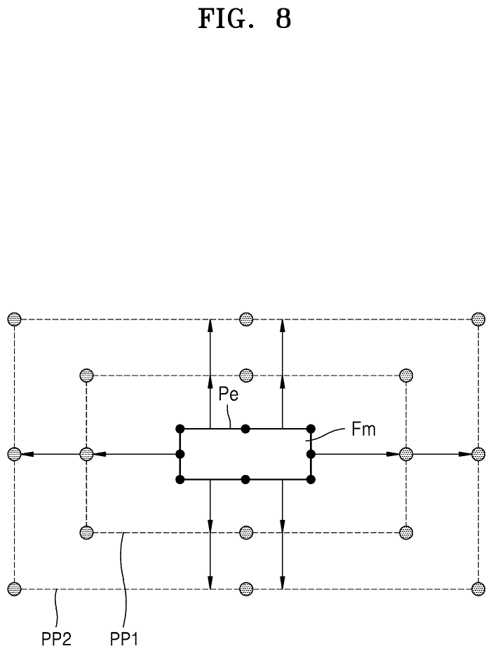

After the main feature Fm is subdivided into the segmentation edges Pe, first and second position polygons PP1 and PP2 in the shape of rectangles are generated at a distance for generating a point cloud map PCM for each of the segmentation edges Pe. In FIG. 8, although two types of position polygons are illustrated, one or three or more types of position polygons may be generated to correspond to one main feature Fm.

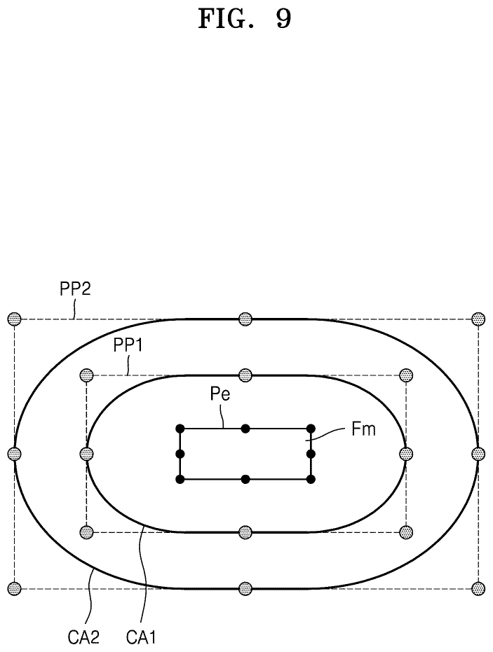

After the first and second position polygons PP1 and PP2 are generated, the first and second position polygons PP1 and PP2 are rounded to generate a plurality of curve axes. In FIG. 9, the first and second position polygons PP1 and PP2 on opposite sides may be rounded in the first horizontal direction (the X-direction) to generate curve axes CA1 and CA2. In an embodiment, the curve axes CA1 and CA2 may be generated based on segments of the first and second position polygons PP1 and PP2. For example, by ensuring that certain points of the line segment satisfy an elliptical equation, the curve axes CA1 and CA2 may be generated so that the lines of the curve axes CA1 and CA2 constitute the corresponding ellipse. In an embodiment, corners of the first position polygon PP1 may be rounded, and the first position polygon PP1 with the rounded corners may be an ellipse satisfying an elliptical equation. Similarly, corners of the second position polygon PP2 may be rounded, and the second position polygon PP2 with the rounded corners may be an ellipse satisfying an elliptical equation. In an embodiment, the curve axes CA1 may refer to a major axis and a minor axis of the ellipse corresponding to the first position polygon PP1, and the curve axes CA2 may refer to a major axis and a minor axis of the ellipse corresponding to the second position polygon PP2.

After the first and second curve axes CA1 and CA2 are generated, curve points CP1 and CP2 are generated on the lines of the curve axes CA1 and CA2. For example, the curve points CP1 may be generated on the perimeter of the ellipse defined by the curve axes CA1, and the curve points CP2 may be generated on the perimeter of the ellipse defined by the curve axes CA2. The curve points CP1 and CP2 may be generated variously on the perimeters of the ellipses defined by the curve axes CA1 and CA2 according to certain rules. For reference, the points on the first and second position polygons PP1 and PP2 of FIG. 8 and the points on the perimeters of the ellipses defined by the curve axes CA1 and CA2 of FIG. 9 may be respectively points corresponding to the subdivision points for segmenting the edge in the main feature Fm.

At least some of the points on the first and second position polygons PP1 and PP2 and points on the curve axes CA1 and CA2 may be combined to generate first and second point cloud maps PCM1 and PCM2. In an embodiment, the points at the vertices of the first and second position polygons PP1 and PP2 may not be included in the point cloud map PCM.

In another embodiment, a rectangular point cloud map PCM may be generated by adding points on line segments of the first and second position polygons PP1 and PP2 of FIG. 9.

Referring to FIG. 12, point cloud maps of each of the first to fifth main features Fm1, Fm2, Fm3, Fm4, and Fm5 may be combined. The point cloud map PCM of each main feature Fm may be combined in a Voronoi diagram manner. The Voronoi diagram may split a plane (or space) based on generating points. The Voronoi diagram may split a plane (or space) into a plurality of polygons. The generating point may be the center point of each main feature Fm. For example, the center point of the first main feature Fm1 may be called a first generating point, and the center point of the second main feature Fm2 may be called a second generating point. When a first point cloud map of the first main feature Fm1 and a second point cloud map of the second main feature Fm2 are combined, a boundary may be formed on a line having a distance from each of the first generating point and the second generating point is the same.

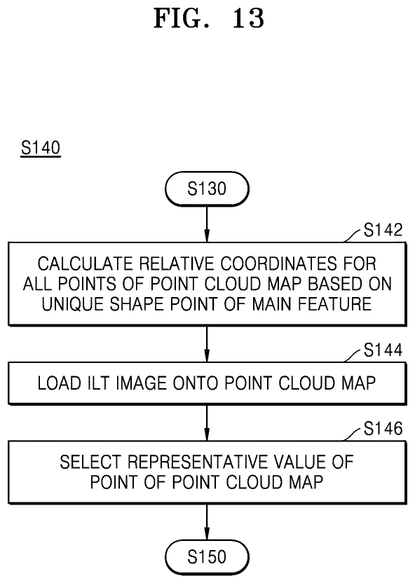

Referring to FIG. 1, after the point cloud map PCM is generated (S130), the point cloud map PCM may be symmetrized (S140). The process of symmetrizing the point cloud map PCM is described with reference to FIG. 13.

FIG. 13 is a flowchart illustrating a process of symmetrizing a point cloud map, according to an embodiment. This is described with reference to FIG. 11.

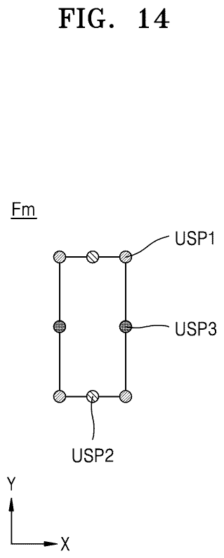

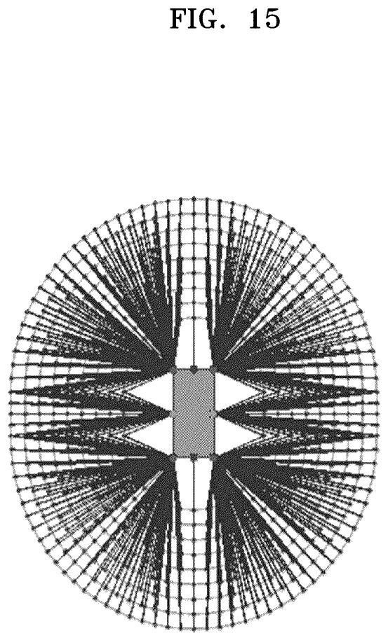

Referring to FIG. 13, first, relative coordinates for all points PT of the point cloud map PCM may be calculated based on a unique shape point of the main feature Fm (S142). The unique shape point may be calculated based on the hash value described above with reference to FIGS. 4 and 5. The operation (S142) of calculating relative coordinates for all points PT of the point cloud map PCM is described with reference to FIGS. 14 and 15.

FIG. 14 is a diagram illustrating the arrangement of unique shape points of a main feature according to an embodiment. FIG. 15 is a diagram illustrating relative coordinates of all points of a point cloud map using each unique shape point of a main feature as a reference point according to an embodiment. This is described with reference to FIG. 11.

Referring to FIG. 14, as described above, points on the main feature Fm may be selected as three types of unique shape points by considering geometrical features. For example, in the main feature Fm of FIG. 14, a unique shape point located at a vertex of the main feature Fm may be referred to as a first unique shape point USP1, a unique shape point on an edge extending in the first horizontal direction (the X-direction) may be referred to as a second unique shape point USP2, and a unique shape point on an edge extending in the second horizontal direction (the Y-direction) may be referred to as a third unique shape point USP3.

Referring to FIG. 15, relative coordinates for all points PT of the point cloud map PCM may be calculated based on each of the first to third unique shape points USP1, USP2, and USP3. That is, the relative coordinates of all points PT of the point cloud map PCM may be calculated based on each unique shape point of the main feature Fm as a reference point. The relative coordinates may be a value obtained by subtracting the coordinates of the unique shape point of the main feature Fm from the absolute coordinates of all points PT of the point cloud map PCM.

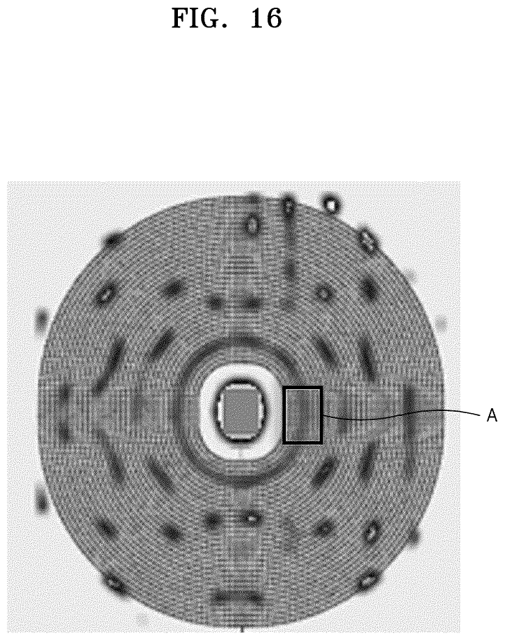

Referring to FIG. 13, after the relative coordinates for all points PT of the point cloud map PCM are calculated (S142), an ILT image may be loaded into the point cloud map PCM (S144). The operation (S144) of loading the ILT image is described with reference to FIGS. 16 to 19.

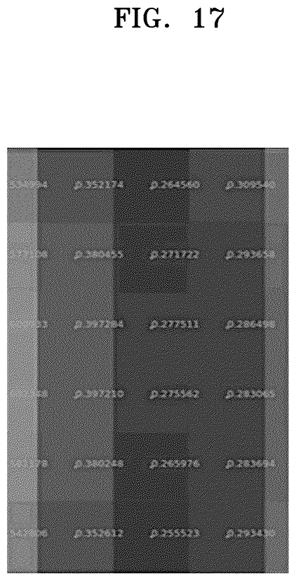

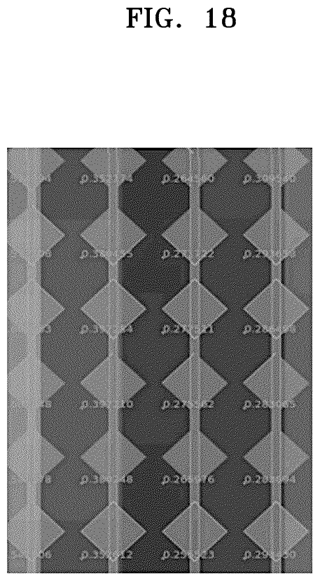

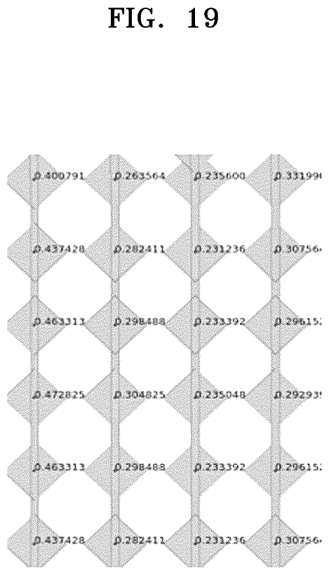

FIG. 16 is a diagram illustrating loading an ILT image onto a point cloud map according to an embodiment. FIG. 17 is a diagram illustrating an ILT image corresponding to region A of FIG. 16, and FIG. 18 is a diagram illustrating a point cloud map and an ILT image corresponding to region A of FIG. 16. FIG. 19 is a diagram illustrating values inside points of a point cloud map corresponding to region A of FIG. 16. In FIGS. 17 and 18, values are displayed for each pixel of the ILT image, and in FIG. 19, values are displayed for each point PT of the point cloud map PCM. This is described with reference to FIG. 11.

Referring to FIGS. 16 to 19, loading an ILT image into the point cloud map PCM may include placing a corresponding position ILT image on the point cloud map PCM. ILT images may have values per pixel. In an embodiment, the values of the pixels of the ILT image may be the light intensity for each pixel. In another embodiment, the values of pixels of the ILT image may be the light transmittance for each pixel. In an embodiment, each pixel of the ILT image may have a value corresponding to a grayscale level. In an embodiment, each pixel value within the ILT image may be normalized. For example, within the ILT image, each pixel may have a value between 0 and 1.

A database unit (DBU) of the ILT image may be different from a DBU of the point cloud map PCM. For example, the minimum length unit of each pixel in the ILT image may be different from the minimum length unit of a point PT in the point cloud map PCM. In an embodiment, the DBU of the ILT image may be larger than the DBU of the point cloud map PCM. In an embodiment, the term database unit (DBU) refers to a standardized unit of measurement for describing geometric shapes and patterns within a design database. For example, the database unit represents the smallest grid or resolution unit in the layout database, and determines the precision of the design geometry and how finely features can be defined.

Therefore, the positions of each pixel in the ILT image may be misaligned from each point PT in the point cloud map PCM. In this case, by interpolating the value of each pixel of the ILT image to each point PT of the point cloud map PCM, each point PT of the point cloud map PCM may have a value.

Thereafter, a representative value for the points PT of the point cloud map PCM may be selected (S146) so that points having the same relative coordinates based on the unique shape point of the main feature Fm have the same value. That is, points with the same relative coordinates from unique shape points with the same hash value in the point cloud map PCM may all be changed to have the same value (e.g., the representative value). Each of the plurality of points may have a representative value. In an embodiment, the maximum, minimum and/or average values of each of the points having the same relative coordinates based on the same type of unique shape point of the main feature Fm may be selected as a representative value of the points.

The operation S146 may be performed within the same patch (intra-patch) and/or between different patches of the same type (inter-patch). The different patches of the same type may refer to patches having the same shape of the main feature Fm and/or the same arrangement of the main feature Fm inside the reference patch. In an embodiment, the operation S146 may be performed in different patches of the same type after performed within the same patch.

As the symmetrizing is performed, the point cloud map PCM may be D2 symmetrized and/or D4 symmetrized. D2 symmetry may refer to a case in which there are two equal parts into which an object may be segmented by rotation, and D4 symmetry may refer to a case in which there are four cases that an object may be segmented into by rotation. For example, a rectangle might be an example of D2 symmetry, and a square may be an example of D4 symmetry.

In an embodiment, n equal parts into which an object may be segmented by rotation (where n is a natural number) may be expressed as Dn symmetry. In the case of Dn symmetry, a target object may rotate by

$$\frac{2 π}{n} rad ( \frac{360 °}{n} )$$

to have the same shape as the original shape of the target object.

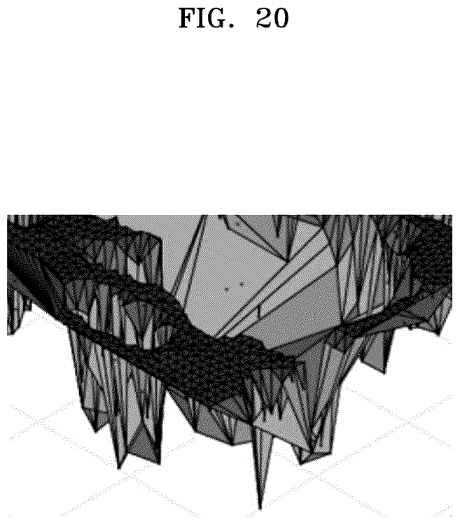

Referring to FIG. 1, after the point cloud map PCM is symmetrized (S140), the point cloud map PCM may be made continuous (S150). The process of serializing the point cloud map PCM is described with reference to FIG. 20. In an embodiment, the serialization of the point cloud map PCM may be a process of converting the point cloud map PCM into a format that can be stored or transmitted and then reconstructed later. When applied to the point cloud map PCM, the serialization may include encoding the point cloud's discrete data points (such as coordinates) into a file or data stream. In an embodiment, the serialization may include interpolation to fill gaps or smooth transitions between discrete points of the point cloud map PCM. The interpolation may make the point cloud map PCM appear more continuous when deserialized.

FIG. 20 is a diagram illustrating a continuous point cloud map according to an embodiment.

Referring to FIG. 20, a continuous point cloud map PCM is illustrated. In an embodiment, a discontinuous point cloud map PCM may be made continuous using a Delaunay triangulation method. A continuous example using the Delaunay triangulation method is shown in FIG. 20. Delaunay triangulation may provide a continuous space from a discrete space. For example, providing a continuous space from a discrete space may be called spatial interpolation.

The point cloud map PCM may include values at discrete points within a plane (or high-dimensional space). For example, as described above with reference to FIGS. 16 to 19, the value of the space in which the point PT is located may be defined, but a value of the space in which the point PT is not located (e.g., between adjacent points PT) may not be defined.

Delaunay triangulation may calculate a value for a space (discontinuity points) between the points PT, based on the coordinates of each point PT in the point cloud map PCM and the values of each point PT (e.g., light intensity at each point PT).

The Delaunay triangulation method may generate a triangular mesh from a set of points (here, the points PT of the point cloud map PCM) in a plane (or high-dimensional space). The triangular mesh may satisfy the conditions that i) the minimum angle of a triangle is maximized and/or ii) no other point is included within the circumcircle of each triangle. By performing interpolation based on the values of the vertices of the triangle formed through the above process, values of regions other than the vertices of the triangle may be calculated. That is, by performing interpolation based on the values of the vertices of the triangles formed through the above process, values (e.g., light intensity between the points PT of the point cloud map PCM) may be provided in a continuous space.

Referring to FIG. 1, after the point cloud map PCM is made continuous (S150), a seed for forming an SRAF may be extracted based on the continuous point cloud map PCM (S160). The seed may be a reference point for determining the placement of SRAF. In an embodiment, the seed may be extracted by differentiating the continuous point cloud map PCM. In an embodiment, a point at which the second derivative of the continuous point cloud map PCM is zero may be extracted as the seed. In the process of extracting the seed, constraints on the seed (e.g., the width of the seed) may be considered.

Thereafter, SRAF may be generated based on the seed (S170). The SRAF may be generated by considering SRAF generating conditions based on the position of the seed. In an embodiment, the SRAF may be generated based on the position of the seed, considering the width of the SRAF, a distance of the SRAF, the area of the SRAF, the length of the SRAF, and/or the angle of the SRAF. In an embodiment, the SRAF may have a curvilinear shape. For example, the dimensions of SRAF may be determined based on the position of the seed.

Later, if the generating conditions for SRAF are changed (for example, if the MRC for SRAF is changed), the SRAF may be easily generated based on the seed extracted in the operation S160.

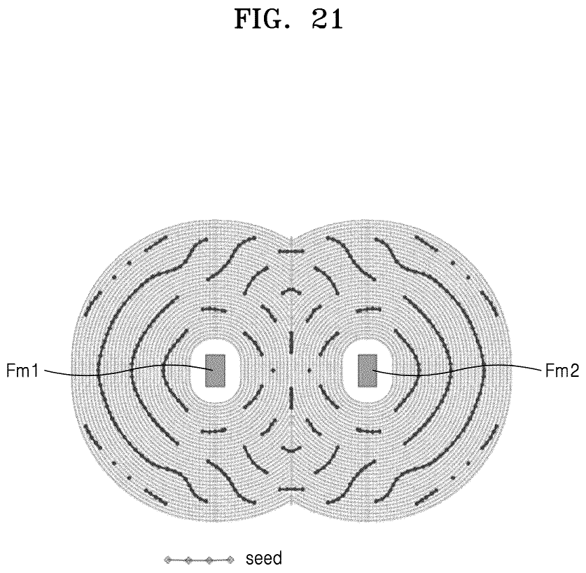

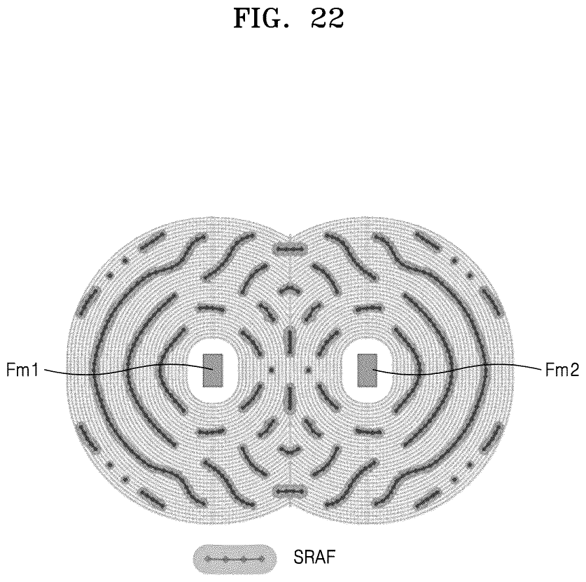

Examples of the operation (S160) of extracting a seed and the operation (S170) of generating SRAF are illustrated in FIGS. 21 and 22.

FIG. 21 is a diagram illustrating a position of a seed extracted from a point cloud map including two main features. FIG. 22 is a diagram illustrating an SRAF generated based on the seed of FIG. 21. In FIG. 21 and FIG. 22, an example is shown in which two main features Fm are arranged.

Referring to FIGS. 21 and 22, as described above, a position at which a seed is to be placed may be extracted from symmetrical and continuous point clouds. Based on the extracted seed, an SRAF may be generated. As described above, the SRAF may be generated by applying SRAF constraints to the extracted seed.

Referring to FIG. 1, after generating the SRAF (S170), MRC may be performed on the SRAF (S175). The operation S175 may include verifying the SRAF length, the SRAF width, the SRAF area, the distance between the SRAF and an adjacent pattern, and/or the angle of the SRAF. In another embodiment, the MRC for SRAF may be omitted.

The SRAF generating method of the inventive concept may include generating a point cloud map PCM, symmetrizing the point cloud map PCM, and serializing the point cloud map PCM. Therefore, an SRAF with increased consistency may be generated. An SRAF with increased consistency may be generated by including symmetrizing the point cloud map PCM between different patches. When manufacturing masks and/or wafers with SRAFs with increased consistency, mask process variations may be reduced and/or wafer critical dimension (CD) variations may be reduced.

The SRAF generating method of the inventive concept may include symmetrizing the point cloud map PCM using a hash value. Therefore, a D2 symmetric and/or D4 symmetric point cloud map PCM may be obtained, and an SRAF with increased consistency may be generated.

In the SRAF generating method of the inventive concept, a patch is split and ILT is performed by considering a unique design so that the number of ILT executions may be reduced and the turn-around time (TAT) of the entire process may be reduced. Therefore, the efficiency of the SRAF generating method may increase.

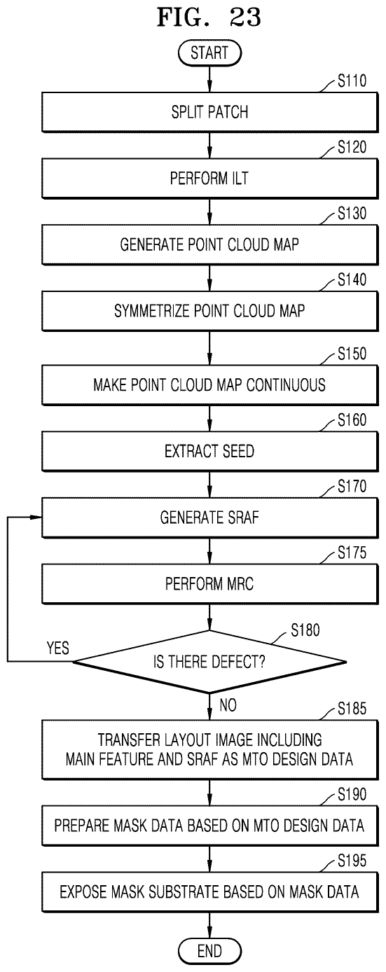

FIG. 23 is a flowchart illustrating a mask manufacturing method according to an embodiment. This is described with reference to FIG. 1.

Referring to FIG. 23, in the mask manufacturing method including the SRAF generating method of the inventive concept (hereinafter, simply referred to as the ‘mask manufacturing method’), an operation (S110) of segmenting a patch to an operation (S175) of performing MRC are sequentially performed. The operation (S110) of segmenting a patch to the operation (S175) of performing MRC are the same as described above in the description of the SRAF generating method in FIG. 1.

After performing MRC (S175), it is determined whether there is a defect (S180). In other words, from MRC execution results, it is determined whether there are any items that violate the MRC conditions in the generated SRAF. If there is a defect (YES), the process proceeds to the operation (S170) of generating SRAF to change the form of SRAF to satisfy the conditions of MRC. For example, the SRAF length, the SRAF width, the SRAF area, the distance between SRAF and an adjacent pattern, and/or the SRAF angle are changed to satisfy the conditions of MRC. Thereafter, the process proceeds to the operation (S175) of performing MRC again.

If there are no defects (NO), a layout image including the main feature Fm and SRAF is transferred, as MTO design data, to a mask manufacturing team (S185). In general, MTO may refer to handing over final mask data acquired via an OPC method to the mask manufacturing team and requesting mask manufacturing. The MTO design data may have a graphic data format used in electronic design automation (EDA) software, etc. For example, the MTO design data may have data formats, such as graphic data system II (GDSII) and open artwork system interchange standard (OASIS).

Thereafter, mask data preparation (MDP) is performed based on the MTO design data (S190). Mask data preparation may include, for example, i) format conversion, called fracturing, ii) augmentation of barcodes for machine reading, standard mask patterns for inspection, job deck, etc., and iii) verification in both automatic and manual manners. The job deck may refer to generating a text file regarding a series of instructions for placement information of multi-mask files, reference dose, exposure speed or method, etc.

After preparing the mask data, a mask substrate is exposed using the mask data, i.e., E-beam data (S195). Exposure may refer to, for example, E-beam writing. E-beam writing may be performed, for example, in a gray writing manner using a multi-beam mask writer (MBMW). E-beam writing may also be performed using a variable shape beam (VSB) exposure device.

After the exposure process, a series of processes may be performed to complete the mask. The series of processes may include, for example, developing, etching, and cleaning. The series of processes for mask manufacturing may include measurement processes, defect inspection, or defect repair processes. A pellicle application process may be included. The pellicle application process may refer to a process of attaching a pellicle to a mask surface to protect the mask from subsequent contamination during delivery and a usable lifespan of the mask, when it is confirmed that there are no contaminants or chemical stains through final washing and inspection.

The mask manufacturing method of the present embodiment may include the method of generating the SRAF of FIG. 1 described above. Accordingly, optimal OPC layout images for masks may be generated, and masks including corresponding patterns may be manufactured accurately with high reliability based on the optimal OPC layout images.

While the inventive concept has been particularly shown and described with reference to embodiments thereof, it will be understood that various changes in form and details may be made therein without departing from the spirit and scope of the following claims.

What is claimed is:

1. A sub-resolution assist feature generating method comprising:
performing inverse lithography technology (ILT) on a first main feature to generating an ILT image;
generating a first point cloud map including a plurality of points for the first main feature;
symmetrizing the first point cloud map based on the ILT image;
serializing the symmetrized first point cloud map;
extracting a seed for generating a sub-resolution assist feature (SRAF), based on the serialized first point cloud map; and
generating the SRAF based on the seed.

2. The sub-resolution assist feature generating method of claim 1,
wherein the symmetrizing of the first point cloud map is performed based on at least one of a segment of interest in the first main feature and a point of interest in the first main feature.

3. The sub-resolution assist feature generating method of claim 2, further comprising:
generating a second point cloud map for a second main feature; and
combining the first point cloud map with the second point cloud map.

4. The sub-resolution assist feature generating method of claim 3,
wherein the combining of the first point cloud map with the second point cloud map is performed based on a Voronoi diagram.

5. The sub-resolution assist feature generating method of claim 1,
wherein the serializing of the first point cloud map is performed using a Delaunay triangulation method.

6. The sub-resolution assist feature generating method of claim 1,
wherein the serializing of the symmetrized first point cloud map includes generating a continuous point cloud map from the first point cloud map, and
wherein the extracting of the seed for generating the SRAF is performed by differentiating the continuous point cloud map.

7. The sub-resolution assist feature generating method of claim 1,
wherein the generating of the SRAF is performed based on at least one of a distance of the SRAF, an area of the SRAF, a length of the SRAF, and an angle of the SRAF which is selected by considering mask rule check (MRC) in the seed.

8. A sub-resolution assist feature generating method comprising:
segmenting a full shot layout into a plurality of patches;
performing inverse lithography technology (ILT) on a main feature of at least one of the plurality of patches to generate an ILT image;
generating a point cloud map including a plurality of points for the main feature;
symmetrizing the point cloud map based on the ILT image;
serializing the symmetrized point cloud map;
extracting a seed for generating a sub-resolution assist feature (SRAF), based on the serialized point cloud map; and
generating the SRAF based on the seed.

9. The sub-resolution assist feature generating method of claim 8,
wherein the performing of the ILT on the main feature is performed on at least one of a segment of interest in the main feature and a point of interest in the main feature.

10. The sub-resolution assist feature generating method of claim 8,
wherein the symmetrizing of the point cloud map based on the ILT image includes:
calculating relative coordinates for all points of the point cloud map;
loading the ILT image onto the point cloud map; and
selecting a value of a point of the point cloud map.

11. The sub-resolution assist feature generating method of claim 10,
wherein the calculating of the relative coordinates for all points of the point cloud map is performed by deducting coordinates of the point of interest in the main feature from absolute coordinates of all points of the point cloud map, based on the point of interest in the main feature.

12. The sub-resolution assist feature generating method of claim 10,
wherein, in the selecting of the value of the point of the point cloud map, the value of the point is calculated by interpolating a value of a pixel of the loaded ILT image.

13. The sub-resolution assist feature generating method of claim 10,
wherein, in the selecting of the value of the point of the point cloud map, a representative value of a point of the point cloud map is selected so that points having the same relative coordinates based on the same point of interest in the main feature have the same value.

14. The sub-resolution assist feature generating method of claim 8,
wherein the performing of ILT on the main feature includes finding at least one of a segment of interest in the main feature and a point of interest in the main feature based on a hash value.

15. The sub-resolution assist feature generating method of claim 8,
wherein the point cloud map is disposed outside the main feature.

16. The sub-resolution assist feature generating method of claim 8,
wherein the point cloud map has an elliptical shape.

17. A mask manufacturing method comprising:
performing inverse lithography technology (ILT) on a main feature to generate an ILT image;
generating a point cloud map including a plurality of points for the main feature;
symmetrizing the point cloud map based on the ILT image;
serializing the symmetrized point cloud map;
extracting a seed for generating a sub-resolution assist feature (SRAF), based on the serialized point cloud map;
generating the SRAF based on the seed;
performing mask rule check (MRC) on the SRAF;
determining whether there is a defect on the SRAF in the performing of the MRC;
transferring a layout image including the main feature and the SRAF as mask tape-out (MTO) design data when there is no defect;
preparing mask data based on the MTO design data; and
exposing a mask substrate based on the mask data.

18. The mask manufacturing method of claim 17, further comprising:
segmenting a full shot layout into a plurality of patches,
wherein the segmenting of the full shot layout into the plurality of patches is performed to minimize a number of patches having different arrangements of main features.

19. The mask manufacturing method of claim 17,
wherein the symmetrizing of the point cloud map based on the ILT image includes:
calculating relative coordinates for all points of the point cloud map;
loading the ILT image onto the point cloud map; and
selecting a value of a point of the point cloud map, and
wherein, in the selecting of the value of the point in the point cloud map, a representative value of the point of the point cloud map is selected so that points having the same relative coordinates based on points of interest having the same hash value of the main feature have the same value within the same patch (intra-patch) or between different patches of the same type (inter-patch).

20. The mask manufacturing method of claim 17,
wherein the serializing of the symmetrized point cloud map includes generating a continuous point cloud map from the point cloud map, and
wherein, in the extracting of the seed for generating the SRAF, a point at which a second derivative value of the continuous point cloud map is 0 is selected as a seed position.
